(19) United States
(12) Patent Application Publication
(10) Pub. No.: US 2015/0382495 A1
(43) Pub. Date: Dec. 31, 2015

(54) MULTI-LAYER PROTECTIVE CASE FOR HANDHELD DEVICES

(71) Applicants: Peng Keong Lim, Loudonville, NY (US); Xinshan Luo, Shanghai (CN)

(72) Inventors: Peng Keong Lim, Loudonville, NY (US); Xinshan Luo, Shanghai (CN)

(21) Appl. No.: 14/314,744

(22) Filed: Jun. 25, 2014

(51) Int. Cl. H05K 5/03; H05K 5/00; A45C 11/00; B65D 81/05

(52) U.S. Cl. CPC H05K 5/03; B65D 81/051; H05K 5/0086; A45C 11/00; A45C 2011/002; A45C 2011/003

(57) ABSTRACT

The present invention generally relates to a protective case for a handheld device. Specifically, embodiments of the present invention provide for a multi-layer protective case that is formed as a single piece apparatus. Each of the multiple layers provides unique characteristics that add to the look, feel, and protection offered by the case.

### FIELD OF THE INVENTION

The present invention generally relates to a protective case for a handheld device. Specifically, embodiments of the present invention provide for a multi-layer protective case that is formed as a single piece apparatus. Each of the multiple layers provides unique characteristics that add to the look, feel, and protection offered by the case.

### BACKGROUND OF THE INVENTION

The owner of a handheld device, such as a mobile phone, tablet computer, PDA, e-book, or similar mobile computing, healthcare or instrumentation device, often times may wish to protect that device with a protective case. Currently available protective cases, however, frequently require a person to choose between form and function. For example, a person may be required to choose between a case that offers great aesthetic appeal with insufficient protective qualities and a case that offers excellent protective features with poor aesthetic appeal. Additionally, many of the currently available protective cases are made from a single type of material that limits the protective benefits the case that can provide. Furthermore, cases that do incorporate multiple types of materials are often a multi-piece design that is bulky and not user friendly.

Therefore, there is a new in the art for a protective case that is multilayered to take advantage of the qualities of multiple different materials, while at the same time being a single piece apparatus to decrease bulk and increase ease of use. These and other features and advantages of the present invention will be explained and will become obvious to one skilled in the art through the summary of the invention that follows.

### SUMMARY OF THE INVENTION

Accordingly, it is an object of the present invention to provide a protective case for a portable or handheld device that incorporates the benefits of a multi-material, multi-layer construction in a protective case that is a single piece.

According to an embodiment of the present invention, a multilayer protective case for a handheld device, the protective case comprising: a front case portion formed with one or more first connection means on one or more edges of the front case portion, and a rear case portion formed with one or more second connection means on one or more edges of the rear case portion and comprising an outer shell formed from a substantially flat back wall and one or more outer shell sidewalls that extend from the back wall, a middle case layer formed with one or more middle case sidewalls that are adapted to fit the handheld device and adapted to be received the outer shell, and an inner case layer adapted to be received by the middle case layer, wherein the each of the first connection means correspond to one of the second connection means to facilitate the attachment of the front case portion to the rear case portion.

According to an embodiment of the present invention, one or more device access openings are formed in the front case portion.

According to an embodiment of the present invention, one or more device access openings are formed in the rear case portion.

According to an embodiment of the present invention, the front case portion is formed as a continuous band that forms an opening for a screen of the handheld device.

According to an embodiment of the present invention, the front case portion is formed as a solid cover adapted to protect a screen of the handheld device.

According to an embodiment of the present invention, the inner case layer is formed with a plurality of cushioned areas adapted to protect the handheld device from shock on an impact.

According to an embodiment of the present invention, the inner case layer is formed as a resilient cushion that is deposited over an interior surface of said middle case layer.

According to an embodiment of the present invention, a multilayer protective case for a handheld device, the protective case comprising: an outer shell formed from a substantially flat back wall and one or more outer shell sidewalls that extend from the back wall, a middle case layer formed with one or more middle case sidewalls that are adapted to fit the handheld device and adapted to be received the outer shell, and an inner case layer adapted to be received by the middle case layer.

According to an embodiment of the present invention, the multilayer protective case further comprises a cover piece formed with one or more cover piece connection means on one or more edges of the cover piece.

According to an embodiment of the present invention, the middle case layer is further comprised of one or more protective case connection means formed on one or more of the middle case sidewalls each of which correspond to one of the cover piece connection means.

According to an embodiment of the present invention, the cover piece is formed as a continuous band that forms an opening for a screen of the handheld device.

According to an embodiment of the present invention, the cover piece is formed as a solid cover adapted to protect a screen of the handheld device.

According to an embodiment of the present invention, the one or more device access openings are formed in the cover piece.

According to an embodiment of the present invention, the one or more device access openings are formed in one or more of the outer shell, the middle case layer, and the inner case layer.

The foregoing summary of the present invention with the preferred embodiments should not be construed to limit the scope of the invention. It should be understood and obvious to one skilled in the art that the embodiments of the invention thus described may be further modified without departing from the spirit and scope of the invention.

### BRIEF DESCRIPTION OF THE DRAWINGS

FIG. 1 is a front perspective view of a handheld device inside of a multilayer protective case, in accordance with an embodiment of the present invention;

FIG. 2 is a rear perspective view of a handheld device inside of a multilayer protective case, in accordance with an embodiment of the present invention;

FIG. 3 is an exploded view of a handheld device inside of a multilayer protective case, in accordance with an embodiment of the present invention;

FIG. 4 is a cross-sectional view of a multilayer protective case, in accordance with an embodiment of the present invention;

FIG. 5 is a rear perspective view of a handheld device inside of a multilayer protective case with a solid front cover, in accordance with an embodiment of the present invention

FIG. 6 is an exploded view of a handheld device inside of a multilayer protective case with a solid front cover, in accordance with an embodiment of the present invention; and

FIG. 7 is a bottom edge view of a handheld device inside of a multilayer protective case with a solid front cover, in accordance with an embodiment of the present invention.

### DETAILED SPECIFICATION

The present invention generally relates to a protective case for a handheld device. Specifically, embodiments of the present invention provide for a multi-layer protective case that is formed as a single piece apparatus. Each of the multiple layers provides unique characteristics that add to the look, feel, and protection offered by the case.

According to an embodiment of the present invention, a multilayer protective case is configured to hold and protect a handheld or similar mobile computing device. In a preferred embodiment, the multilayer protective case may be configured to hold any variety of handheld devices, including, but not limited to mobile phones, tablets, portable computers, PDAs, and e-books. In the preferred embodiment, a multilayer protective is made from a plurality of different materials to take advantage of the unique characteristics of each of those materials and thereby offer the ideal combination of protection and aesthetic appeal. One of ordinary skill in the art would appreciate that multilayer protective case could be configured to accept any number of handheld or other similar mobile computing devices, and embodiments of the present invention are contemplated for use with any such handheld or mobile computing device.

According to a preferred embodiment of the present invention, the multilayer protective case may be configured as a single piece product. In the preferred embodiment, the multilayer protective case is configured as a single piece product with three layers of protection integrated into one continuous piece. In alternate embodiments, there may be additional or fewer layers of production depending upon the application the protective case is being used for. In an alternate preferred embodiment of the present invention, the multilayer protective case may be configured as multi-piece product. In the alternate preferred embodiment, each layer of the multilayer protective case is a separate piece. One of ordinary skill in the art would appreciate there are many suitable configurations and combinations for the layers of the multilayer protective case, and embodiments of the present invention are contemplated for use with any such configuration or combination.

According to an embodiment of the present invention, a protective case for a handheld is comprised of multiple layers of material that form a single cohesive unit. In a preferred embodiment, each of the layers of the protective case is made of a different material thereby allowing the case to enjoy the beneficial characteristics of each of those materials. As an illustrative example, the outer layer of the case may be a hard, durable material that provides maximum protection against wear, scratches, and other similar damage, while the inner layer may be comprised of a soft, resilient material to absorb the shock from drops and other impacts. Additionally, the use of different materials allows for a configuration of the multilayer protective case that maximizes both the protective capabilities of the case, as well as the aesthetic appeal of the case. In an alternate embodiment, each layer is made from a plurality of different materials in order to further maximize the benefits of each of the materials used in a given layer. One of ordinary skill in the art would appreciate there are a number of suitable design configurations for constructing a multilayer protective case, and embodiments of the present invention are contemplated for use with any such design configuration.

According to an embodiment of the present invention, a multilayer protective case for a handheld is comprised of a plurality of different materials in order to take advantage of the unique protective and visual characteristics of each of those materials. In a preferred embodiment, the various layers of the case may be comprised of a variety of materials, including, but not limited to, rubber, metal, rigid plastics (e.g. thermoplastic polycarbonate and acrylic glass), and pliable plastics (e.g. silicon and thermoplastic polyurethane). One of ordinary skill in the art would appreciate that there are numerous materials that are suitable for use in a multilayer protective case, and embodiments of the present invention are contemplated for use with any such material.

According to an embodiment of the present invention, a multilayer protective case is comprised of multiple different layers. In a preferred embodiment, the multilayer protective case is comprised of a front case portion and a rear case portion. In an alternate preferred embodiment, the multilayer protective case is comprised only of the components of the rear case portion. In further alternate embodiments, the multilayer protective case may include fewer or additional components based upon the intended application of the case, as well as the handheld device that is designed to protect. One of ordinary skill in the art would appreciate that a multilayer protective case could be configured with any number of components, and embodiments of the present invention are contemplated for use with any such component.

According to an embodiment of the present invention, a multilayer protective case is comprised of a front case portion, which also may be referred to as a cover piece or front cover. In a preferred embodiment, the front case portion may be formed with a connection means. In the preferred embodiment, the one or more connection means are formed at one or more of the edges of the front case portion. The connection means on the front case portion may also be referred to as the cover piece connection means, front case connection means, front cover connection means, or first connection means. In the preferred embodiment, the front cover connection means attaches to corresponding connection means on the rear case portion of the multilayer case (or a component of the rear case portion). Suitable connection means include, but, are not limited to, snap-fit and friction fit. One of ordinary skill in the art would appreciate that there are many suitable designs for a front case portion, and embodiments of the present invention are contemplated for use with any such design.

According to an embodiment of the present invention, the front case portion may be configured as trim piece or bezel cover for the handheld device. In a preferred embodiment, the front case portion is formed as a continuous band that forms an opening for a screen of a handheld device. In that embodiment, the material forming the front case portion matches the shape of the front bezel of the handheld device and is open in the middle so that the front case portion is essentially a trim piece that goes around the edges of the handheld device. One of ordinary skill in the art would appreciate there are many suitable designs for a front case portion, and embodiments of the present invention are contemplated for use with any such design.

According to an embodiment of the present invention, the front case portion may be configured as a protective cover for the handheld device. In a preferred embodiment, the front case portion is formed as a protective cover that is a solid piece of material that protects the screen of the handheld device. One of ordinary skill in the art would appreciate there are many suitable designs for a front case portion, and embodiments of the present invention are contemplated for use with any such design.

According to an embodiment of the present invention, a multilayer protective case is comprised of a rear case portion. In a preferred embodiment, the rear case portion may be comprised of an outer shell, a middle case layer, an inner case layer, and one or more connection means. In an alternate preferred embodiment, the entire protective case is formed from only the components of the rear case portion (i.e. outer shell, middle case layer, and inner case layer). Other embodiments of rear case portion may include additional or fewer components. One of ordinary skill in the art would appreciate that there are many suitable designs for a rear case portion, and embodiments of the present invention are contemplated for use with any such design.

According to an embodiment of the present invention, the rear case portion may be comprised of an outer shell. In a preferred embodiment, the outer shell is comprised of a substantially flat back wall and one or more sidewalls that extend from the back wall. In the preferred embodiment, the sidewalls are formed to accommodate a given handheld device, as well as the middle case layer and the inner case layer of the rear case portion. In the preferred embodiment, the outer shell is comprised of a durable material to offer maximum protection to the handheld device. In some embodiments, the outer shell may be constructed from a metal material in order to provide a premium quality look and feel over more commonly used plastic materials. One of ordinary skill in the art would appreciate there are many suitable designs for an outer shell, an embodiments of the present invention are contemplated for use with any such designs.

According to an embodiment of the present invention, the rear case portion may be comprised of middle case layer. In a preferred embodiment, the middle case layer may be formed with one or more side walls that are adapted to form fit to a handheld device. In the preferred embodiment, the middle case layer is further adapted to receive the inner case layer, while being itself received by the outer shell. In the preferred embodiment, the middle case layer may be the component of the rear case portion that is configured with the one or more connection means. In some embodiments, the middle case layer is constructed from plastic. One of ordinary skill in the art would appreciate there are many suitable designs for a middle case layer, an embodiments of the present invention are contemplated for use with any such designs.

According to an embodiment of the present invention, the rear case portion may be comprised of an inner case layer. In a preferred embodiment, the inner case layer is adapted to be received by the middle case layer. In the preferred embodiment, the inner case layer is made from a resilient material that is adapted to absorb the shock of impacts. The inner case layer may be configured with a plurality of cushioned areas that are further adapted absorb shocks and other impacts. In the preferred embodiment, these cushioned areas may be mounded or pillow-like pads or padding areas that are formed on the inner case layer. One of ordinary skill in the art would appreciate there are many suitable designs for an inner case layer, an embodiments of the present invention are contemplated for use with any such designs.

According to an embodiment of the present invention, the rear case portion of the multilayer protective case may be formed with one or more connection means. In a preferred embodiment, the one or more connection means are formed at one or more of the edges of the rear case portion or on one of the individual components of the rear case portion (e.g. the outer shell, middle case layer, and inner case layer). The connection means on the rear case portion may also be referred to as the rear case connection means or second connection means. In the preferred embodiment, the rear case connection means attaches to corresponding connection means on the front cover portion of the multilayer case. Suitable connection means include, but, are not limited to, snap-fit and friction fit. One of ordinary skill in the art would appreciate there are many suitable connection means that might be used on the rear case portion, and embodiments of the present invention are contemplated for use with any such connection means.

According to an embodiment of the present invention, the multilayer protective case may be configured with one or more device access openings. In a preferred embodiment, the device access openings may be formed in the front case portion, rear case portion, individual component of the rear case portion (i.e. the outer shell, middle case layer, and inner case layer), or any combination thereof. In the preferred embodiment, the device access openings allow a user to access certain inputs and outputs that are on the handheld device, including, but not limited to buttons, speakers, microphones, headphone jacks, displays, power/charging connections, touchscreens, and sensors. One of ordinary skill in the art would appreciate that there are a variety of suitable arrangements for the device access openings, and embodiments of the present invention are contemplated for use with any such arrangement.

According to an embodiment of the present invention, the multilayer protective case may be configured with one or more input button guards. In a preferred embodiment, the input button guards may be formed on the front case portion, rear case portion, individual component of the rear case portion (i.e. the outer shell, middle case layer, and inner case layer), or any combination thereof. In the preferred embodiment, the input button guards cover input buttons on the handheld device to protect those input buttons from dirt, dust, grime, and other damage. The input button guards could be configured to cover any variety of input buttons including, but not limited to, power switches, volume buttons, keyboards, and navigation keys. One of ordinary skill in the art would appreciate that there are a variety of suitable arrangements for the input button guards, and embodiments of the present invention are contemplated for use with any such arrangement.

According to a preferred embodiment of the present invention, the multilayer protective case may be produced through a molding process. In a first preferred embodiment, the multilayer protective case is formed by a double-shot molding process whereby the middle case layer is formed first, with the inner case layer being formed immediately thereafter by injecting material into the middle case layer that was previously formed to provide a single, combined unit. The outer shell is then pressed together with the combined middle case layer and inner case unit and an adhesive is used to bind those two components together to form a single, cohesive multilayer case. In a second preferred embodiment, the multilayer protective case is formed by a triple-shot molding process whereby the outer shell is formed first, with the middle case layer then being molded onto the outer shell, and finally the inner case layer being molded onto the middle case layer. In an alternate embodiment, each of the layers (i.e. the outer shell, middle case layer, and inner case layer) may be joined together through the use of adhesives. One of ordinary skill in the art would appreciate that there are many methods for producing a multilayer protective case, and embodiments of the present invention may assembled through any such production method.

### Exemplary Embodiments

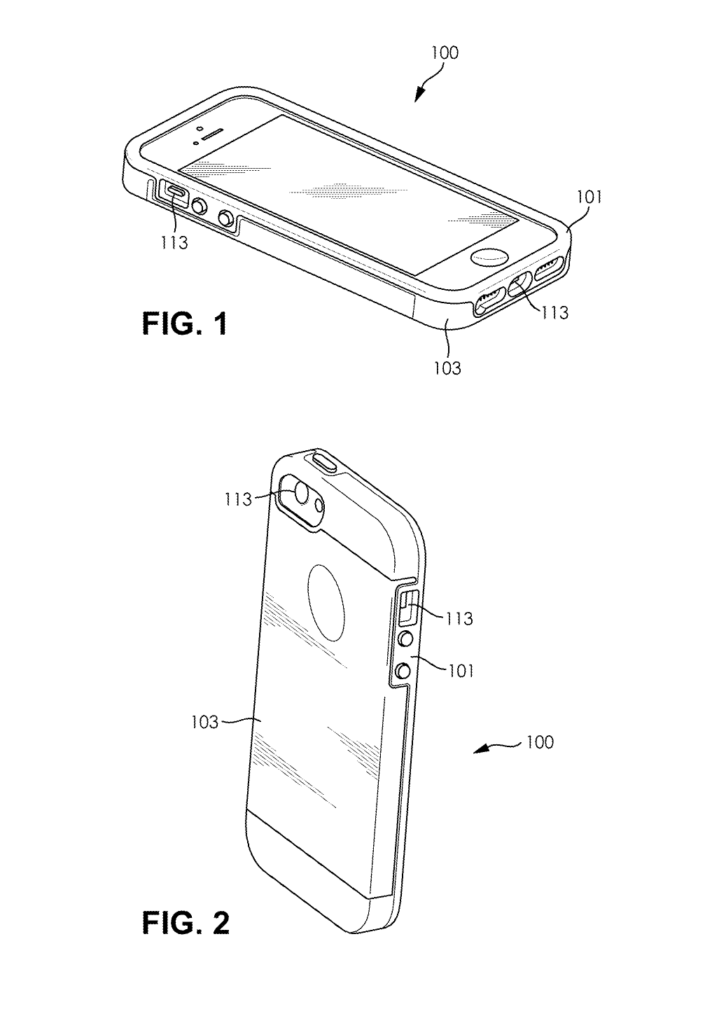

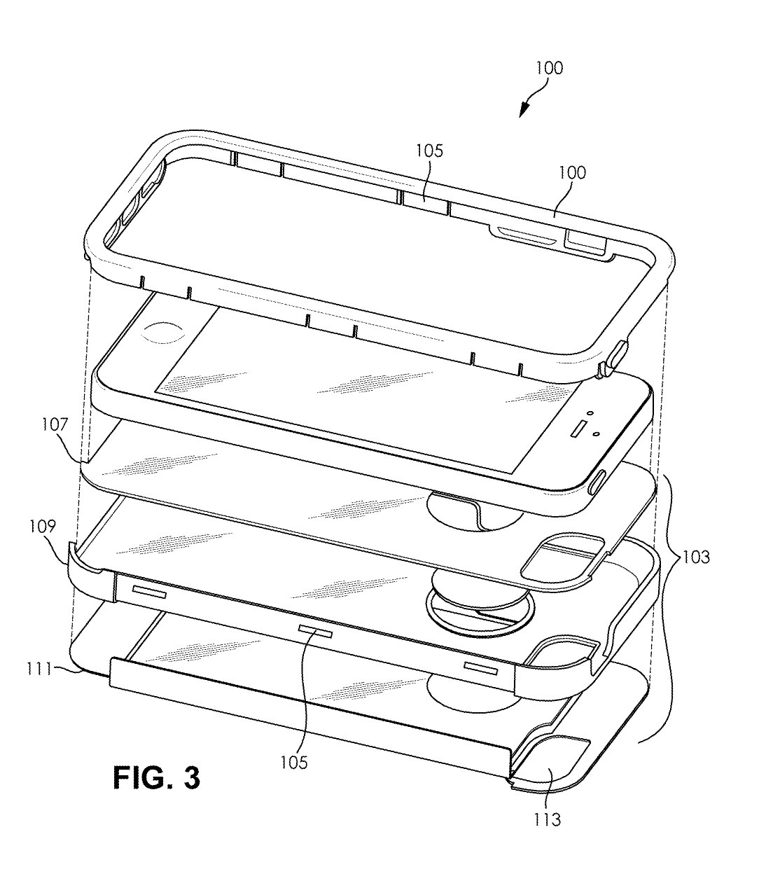

Turning now to FIGS. 1-3, an exemplary embodiment of a multilayer protective case in accordance with an embodiment of the present invention. In this exemplary embodiment, the multilayer case 100 includes a front case portion 101 that is configured as a trim piece or bezel guard that attaches around the front edges of the handheld device. In a preferred embodiment, the multilayer protective case 100 includes a front case portion 101, a rear case portion 103, a connection means 105 (on both the front case portion and rear case portion), and a plurality of device access openings 113. In the preferred embodiment, the rear case portion is comprised of an outer shell 111, a middle case layer 109, and an inner case layer 107.

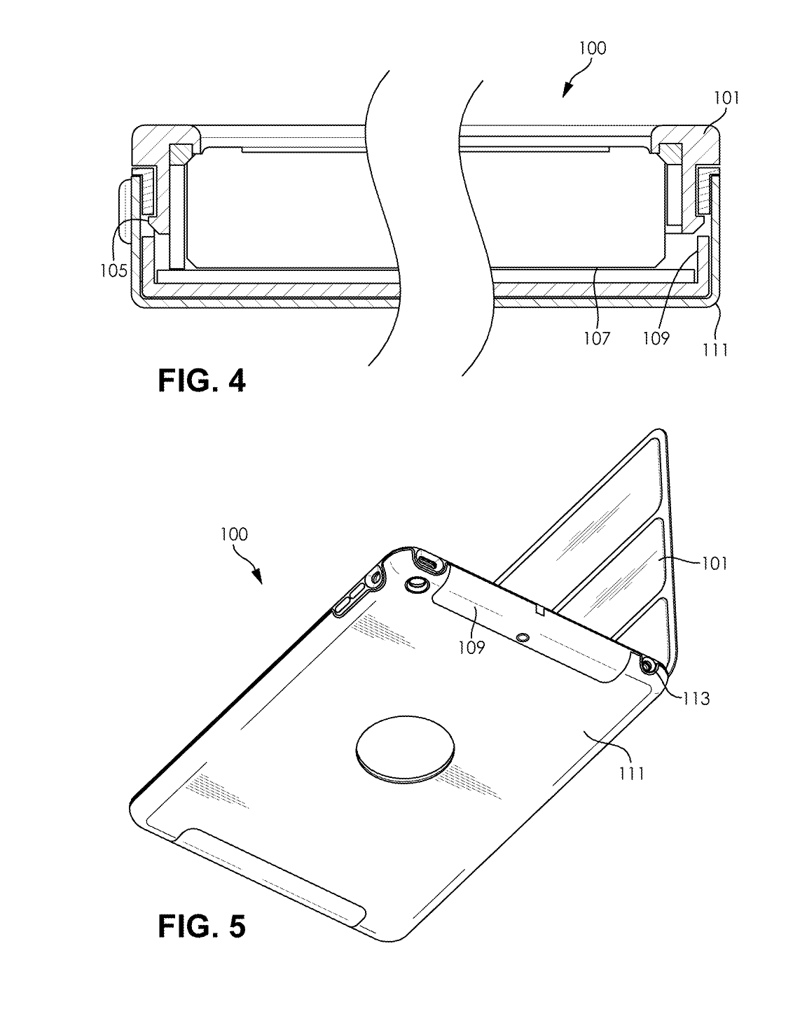

Turning now FIG. 4, a cross-sectional view of an exemplary embodiment of a multilayer protective case in accordance with an embodiment of the present invention. In this exemplary embodiment, the multilayer case 100 includes a front case portion 101 that is configured as a trim piece or bezel guard that attaches around the front edges of the handheld device. In a preferred embodiment, the multilayer protective case 100 includes a front case portion, a rear case portion 103, and a connection means 105 (on both the front case portion 101 and rear case portion 103). In the preferred embodiment, the rear case portion is comprised of an outer shell 111, a middle case layer 109, and an inner case layer 107. In this view, the alignment of the front case portion 101, as well as the outer shell 111, middle case layer 109, and inner case layer 107 of the rear case portion 103 can be plainly seen. In particular, this view shows the connection between the connection means 105 of the front case portion 101 and the connection means 105 of the rear case portion 101 (which is located on the sidewall of the middle case layer 109).

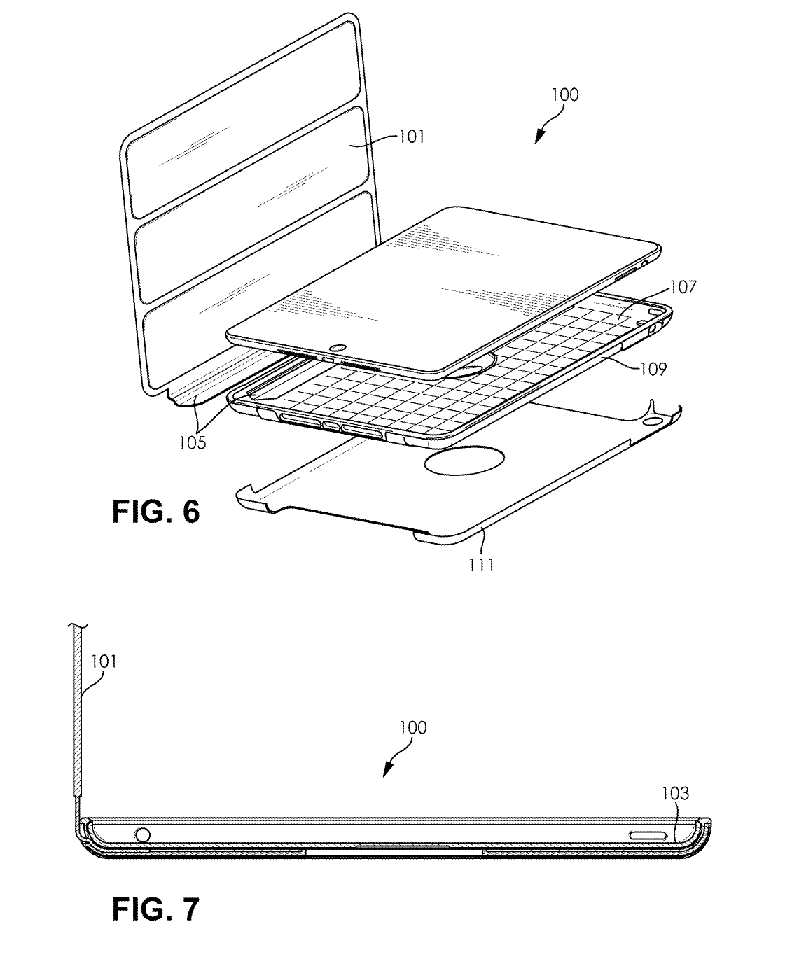

Turning now to FIGS. 5-7, an exemplary embodiment of a multilayer protective case in accordance with an embodiment of the present invention. In this exemplary embodiment, the multilayer case 100 includes a front case portion 101 that is configured as solid cover that attaches to the rear case portion 103 to provide a protective cover for the screen of the handheld device. In a preferred embodiment, the multilayer protective case 100 includes a front case portion 101, a rear case portion 103, a connection means 105 (on both the front case portion 101 and rear case portion 103), and a plurality of device access openings 113. In the preferred embodiment, the rear case portion is comprised of an outer shell 111, a middle case layer 109, and an inner case layer 107.

While multiple embodiments are disclosed, still other embodiments of the present invention will become apparent to those skilled in the art from this detailed description. The invention is capable of myriad modifications in various obvious aspects, all without departing from the spirit and scope of the present invention. Accordingly, the drawings and descriptions are to be regarded as illustrative in nature and not restrictive.

1. A multilayer protective case for a handheld device, the protective case comprising:
a front case portion formed with one or more first connection means on one or more edges of said front case portion; and
a rear case portion formed with one or more second connection means on one or more edges of said rear case portion and comprising
an outer shell formed from a substantially flat back wall and one or more outer shell sidewalls that extend from said back wall,
a middle case layer formed with one or more middle case sidewalls that are adapted to fit said handheld device and adapted to be received said outer shell,
and an inner case layer adapted to be received by said middle case layer,
wherein said each of said first connection means correspond to one of said second connection means to facilitate the attachment of said front case portion to said rear case portion.

2. The protective case of claim 1, wherein one or more device access openings are formed in said front case portion.

3. The protective case of claim 1, wherein one or more device access openings are formed in said rear case portion.

4. The protective case of claim 1, wherein said front case portion is formed as a continuous band that forms an opening for a screen of said handheld device.

5. The protective case of claim 1, wherein said front case portion is formed as a solid cover adapted to protect a screen of said handheld device.

6. The protective case of claim 1, wherein said inner case layer is formed with a plurality of cushioned areas adapted to protect said handheld device from shock on an impact.

7. The protective case of claim 1, wherein said inner case layer is formed as a resilient cushion that is deposited over an interior surface of said middle case layer.

8. A multilayer protective case for a handheld device, the protective case comprising:
an outer shell formed from a substantially flat back wall and one or more outer shell sidewalls that extend from said back wall;
a middle case layer formed with one or more middle case sidewalls that are adapted to fit said handheld device and adapted to be received said outer shell; and
an inner case layer adapted to be received by said middle case layer.

9. The protective case of claim 8, further comprising a cover piece formed with one or more cover piece connection means on one or more edges of said cover piece.

10. The protective case of claim 9, wherein said middle case layer is further comprised of one or more protective case connection means formed on one or more of said middle case sidewalls each of which correspond to one of said cover piece connection means.

11. The protective case of claim 9, wherein said cover piece is formed as a continuous band that forms an opening for a screen of said handheld device.

12. The protective case of claim 9, wherein said cover piece is formed as a solid cover adapted to protect a screen of said handheld device.

13. The protective case of claim 9, one or more device access openings are formed in said cover piece.

14. The protective case of claim 8, wherein one or more device access openings are formed in one or more of said outer shell, said middle case layer, and said inner case layer.

15. The protective case of claim 8, wherein said inner case layer is formed with a plurality of cushioned areas adapted to protect said handheld device from shock of an impact.

16. The protective case of claim 8, wherein said inner case layer is formed as a resilient cushion that is deposited over an interior surface of said middle case layer.
